(19) United States
(12) Patent Application Publication
(10) Pub. No.: US 2008/0206653 A1
(43) Pub. Date: Aug. 28, 2008

(54) EXPOSURE MASK

(75) Inventor: Minoru Sugawara, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/033,612

(22) Filed: Feb. 19, 2008

(30) Foreign Application Priority Data
Feb. 22, 2007 (JP) 2007-041774

(51) Int. Cl. G03F 1/00

(52) U.S. Cl. 430/5

(57) ABSTRACT

Disclosed herein is an exposure mask for use in manufacturing a semiconductor device through exposure conducted by use of extreme ultraviolet rays, including, an absorbing film configured to absorb the extreme ultraviolet rays, and a mask blank having the function of reflecting the extreme ultraviolet rays, wherein the thickness of the absorbing film is so determined that the contrast of an optical image transferred onto a wafer by use of the exposure mask will have a maximal value.

### CROSS REFERENCES TO RELATED APPLICATIONS

The present invention contains subject matter related to Japanese Patent Application JP 2007-041774 filed in the Japan Patent Office on Feb. 22, 2007, the entire contents of which being incorporated herein by reference.

### BACKGROUND OF THE INVENTION

1. Field of the Invention

The present invention relates to an exposure mask for use in manufacturing a semiconductor device through exposure conducted by use of extreme ultraviolet (EUV) rays.

2. Description of the Related Art

In recent years, along with reductions in the size of semiconductor devices, there has been an increasing demand for size reduction as to the line width in a resist pattern formed by exposure of a resist applied as a photosensitive material to a wafer substrate, followed by development of the exposed resist, and a circuit pattern obtained by etching conducted using the resist pattern as an etching mask. Besides, further size reductions are demanded not only as to the pattern width (line width) but also as to pattern pitch or memory cell pitch.

Hitherto, the demand for further size reductions as to not only pattern width (line width) but also pattern pitch or memory cell pitch has been met by use of more shorter-wavelength rays for exposure of the resist. For example, exposure rays with a wavelength of 350 nm have been used for semiconductor devices based on 365 nm design rule, exposure rays with a wavelength of 248 nm for semiconductor devices based on 250 to 130 nm design rules, exposure rays with a wavelength of 193 nm for semiconductor devices based on 130 to 65 nm design rules, and so on. Furthermore, it is being attempted to use exposure rays with a wavelength of 157 nm, or use an immersion lens having the effect of effectively shortening the wavelength of ultraviolet rays or the effect of enlarging the numerical aperture of lens. The resolution at a certain exposure wavelength is known to be expressed by the Rayleigh's formula, i.e., the following formula (1):

ω=k₁×(λ/NA) (1)

In the formula, ω is the minimum-width pattern to be resolved, NA is the numerical aperture of the lens in the projection optical system, λ is the wavelength of the exposure rays, and k1 is a process constant which is determined mainly by the resist performance, the selection of a super-resolving technique, etc. It is known that the use of an optimum resist and super-resolving technique permits selections ranging to a k1 value of about 0.35 in photolithography according to the related art.

For example, the minimum pattern width in the case where a wavelength of 193 nm is used is 48 nm if an immersion lens with NA=1.4 is used. The super-resolving technique mentioned here is a technique aiming at obtaining a pattern smaller than the wavelength of rays used, by selectively using the ±1 order diffracted rays of the rays having been transmitted through the mask and diffracted by a light shielding pattern on the mask.

In order to obtain a pattern smaller than 48 nm, it may be necessary to use exposure rays with a further shorter wavelength. Therefore, use of extreme ultraviolet rays with a wavelength centered on 13.5 nm as exposure rays is being developed vigorously. For rays with wavelengths ranging down to 157 nm, there are materials capable of transmitting the rays, such as calcium fluoride (CaF₂) and silicon oxide (SiO₂), so that it is possible to fabricate masks and optical systems with light-transmitting configurations.

However, in the case of extreme ultraviolet rays with more shorter wavelengths (for example, ultraviolet rays with wavelengths of 5 to 100 nm), there is no material that is transmissive to the rays, so that the masks and optical systems for use with such ultraviolet rays are configured to be reflective masks and reflective optical systems (refer to, for example, Japanese Patent Laid-open No. 2002-280291 and JP-A-2005/505930). The rays reflected on the mask plane must be guided to a projection optical system without any interference with the rays incident on the mask; therefore, the rays incident on the mask will necessarily be in a skew incidence mode, i.e., a mode of incidence at a certain angle relative to the normal to the mask plane. This angle is determined by the NA of the projection optical system, the mask magnification factor m, and the size σ of the illumination light source. For example, in the case where a mask with a reduction ratio (demagnification factor) of 4 is used over a wafer, it would be necessary for the exposure rays, in an exposure system with NA=0.3, to be incident on the mask at an angle of incidence greater than 4.30 degrees against the normal to the mask plane. Similarly, in an exposure system with NA=0.25, it would be necessary for the exposure rays to be incident on the mask at an angle of not less than 3.58 degrees. In practice, an exposure system is designed with an angle of incidence on masks which is greater than the above-mentioned angle value, for such reasons as limitations in regard of spatial arrangement of the optical system including mirrors and a reduction in designed residual aberration. For example, in an exposure system with NA=0.25, a design is adopted in which the angle of incidence is not less than 6 degrees. Similarly, in an exposure system with NA=0.30, a design is adopted in which the angle of incidence is not less than 7 degrees.

Here, in the related art, the thickness of the absorbing film for forming an absorption pattern of the above-mentioned reflective mask has been obtained from the conditions for ensuring that the ratio of the reflectance of the absorbing film to the reflectance of a reflective multilayer film blank satisfying the Bragg reflection condition at the wavelength of the exposure rays, or the reflectance contrast, will have a minimal value (local minimum).

### SUMMARY OF THE INVENTION

As above-mentioned, there has been a problem in that the absorbing film thickness condition for bringing the reflectance contrast to a minimal value (local minimum) and the absorbing film thickness condition for bringing the contrast of the image transferred onto the wafer to a maximal value (local maximum) do not conform to each other. Therefore, when the absorbing film thickness condition for bringing the reflectance contrast to a minimal value in the method according to the related art is used, the contrast of the image transferred onto the wafer would be lowered, making it very difficult to form a good pattern on the wafer.

Thus, there is need to enhance the performance of semiconductor devices, by use of a reflective mask such that the contrast of the transferred image on a wafer can be restrained from being lowered and that both a good contrast of the transferred image on the wafer and a good reflectance contrast can simultaneously be realized.

According to one embodiment of the present invention, there is provided an exposure mask for use in manufacturing a semiconductor device through exposure conducted by use of extreme ultraviolet rays, including: an absorbing film for absorbing the extreme ultraviolet rays, and a mask blank having the function of reflecting the extreme ultraviolet rays, wherein the thickness of the absorbing film is so determined that the contrast of an optical image to be transferred onto a wafer by use of the exposure mask will have a maximal value.

In the one embodiment of the present invention as above, the thickness of the absorbing film is so determined that the contrast of the optical image to be transferred onto the wafer will have a maximal value, whereby the contrast of the transferred image on the wafer is brought to a maximal value. Accordingly, an exposure mask for use with extreme ultraviolet rays which has good transfer characteristics can be obtained.

According to the one embodiment of the present invention, it is ensured that, in a reflective exposure mask for use with extreme ultraviolet rays, both a good contrast of a transferred image on a wafer and a good reflectance contrast can simultaneously be realized. As a result, it is possible to enhance the performance of semiconductor devices manufactured by use of this exposure mask.

### BRIEF DESCRIPTION OF THE DRAWINGS

FIG. 1 is a schematic perspective view showing an example of an exposure mask based on the present invention;

FIG. 2 is a diagram showing the relationship between the thickness the reflectance contrast of an absorbing film (Ta film), at an angle of skew incidence over the exposure mask of 6.6°, in the case where the material of the absorbing film for absorbing extreme ultraviolet rays is tantalum (Ta);

FIG. 3 is a diagram showing the relationship between the position in a pattern on a wafer and the light intensity on the wafer;

FIGS. 4A and 4B are diagrams showing the relationship between the thickness of the absorbing film (tantalum film) and the NILS, at CD 22 nm/pattern pitch 44 nm;

FIGS. 5A and 5B are diagrams showing the relationship between the thickness of the absorbing film (tantalum film) and the NILS, at CD 22 nm/pattern pitch 88 nm;

FIGS. 6A and 6B are diagrams showing the relationship between the thickness of the absorbing film (tantalum film) and the NILS, at CD 44 nm/pattern pitch 88 nm.

### DETAILED DESCRIPTION OF THE PREFERRED EMBODIMENTS

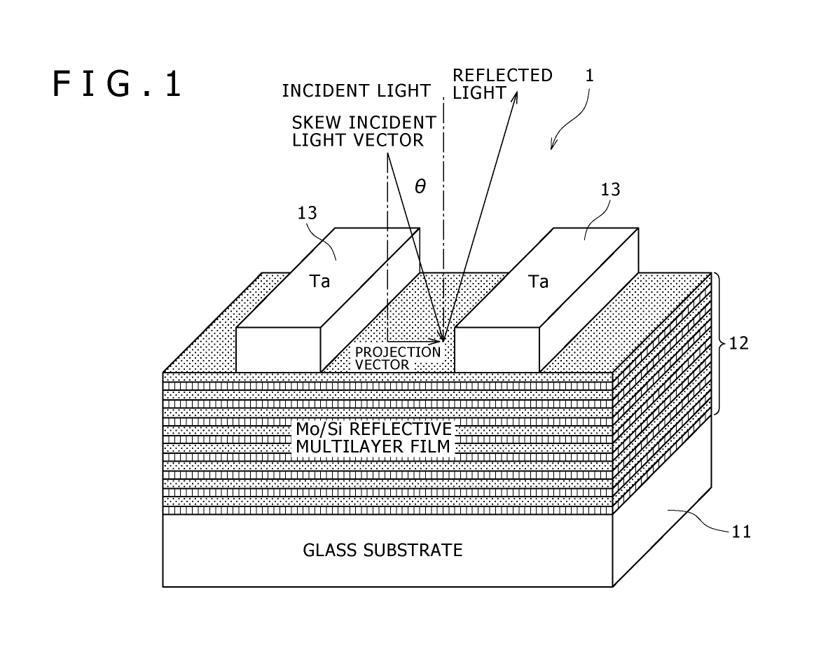

Now, a reflective type exposure mask for use with extreme ultraviolet rays as exposure light will be described as an example of the exposure mask based on the present invention, referring to the schematic perspective view shown in FIG. 1.

As shown in FIG. 1, the exposure mask 1 according to an embodiment of the present invention has a mask blank 12 including a reflective multilayer film having a multiplicity of molybdenum (Mo) layers and silicon (Si) layers, and an absorbing film 13 for absorbing extreme ultraviolet rays is formed on the mask blank 12 by use of, for example, a tantalum (Ta) film. The absorbing film 13 is formed in a desired pattern shape.

The thickness of the absorbing film 13 is so determined that the contrast of an optical image transferred onto a wafer (not shown) by use of the exposure mask 1 will have a maximal value (if possible, a maximum). In addition, the thickness of the absorbing film 13 is so determined that the contrast of the optical image transferred onto the wafer (not shown) by use of the exposure mask 1 will have a maximal value and that the reflectance contrast between the absorbing film 13 and the mask blank 12 will be not more than a desired value, for example, not more than 1.0%. Alternatively, the thickness may be so determined that the reflectance contrast will have a minimal value (if possible, a minimum); in this case, naturally, the thickness is so determined that the contrast of the optical image will have a maximal value (if possible, a maximum).

On the other hand, in the related art, the thickness of the absorbing film in an exposure mask for use with extreme ultraviolet rays has been obtained under the conditions for minimizing the value of the following formula (1):

Rr=Ra/Rb (1),

where Ra is the reflectance of the absorbing film, Rb is the reflectance of a Mo/Si reflective multilayer film capable of embodying a Bragg reflection condition suited to an exposure wavelength of 13.5 nm, and Rr is the reflectance contrast.

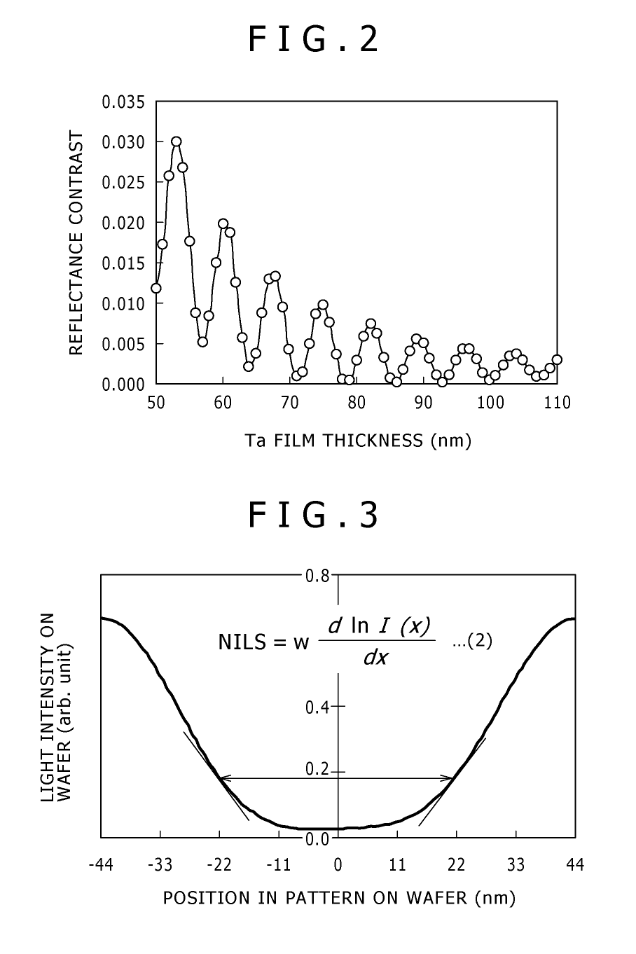

FIG. 2 is a diagram showing the relationship between the thickness and the reflectance contrast of a absorbing film (Ta film), at an angle of skew incidence over the exposure mask of 6.6°, in the case where the material of the absorbing film for absorbing extreme ultraviolet rays is tantalum (Ta).

As shown in FIG. 2, the thickness values of the absorbing film (Ta film) such as to bring the reflectance contrast to a minimal value are 57 nm, 64 nm, 71 nm, 79 nm, 86 nm, 93 nm, 100 nm and 108 nm.

In addition, as shown in FIG. 3 which shows the relationship between the position in the pattern on the wafer and the light intensity on the wafer, the contrast of the optical image on the wafer is obtained from the normalized image log-slope (NILS). This is defined by the log-slope (logarithmic gradient) at an optical image edge for obtaining the desired line width, and is given by the following formula (2):

NILS=w·[dln{I(x)}/dx] (2)

In the formula, x is a pattern index, I(x) is the light intensity at position x, and w is the desired line width on the wafer.

The normalized image log-slope (hereinafter referred to as NILS) for the thickness of the absorbing film is obtained with the exposure mask 1 configured as shown in FIG. 1. More specifically, this corresponds to the case where the projection vector obtained by projecting the skew incident light vector over the mask onto the mask top surface is orthogonal to an edge of a line-and-space pattern of the absorbing film 13. Here, a bias correction for thinning the pattern width of the absorbing film 13 on the mask is preliminarily conducted so that the transferred line width on the wafer will be substantially the same as that in the case where the projection vector obtained by projecting the skew incident light vector over the mask onto the mask top surface is parallel to the edge of the line-and-space pattern of the absorbing film 13.

Here, the NILS is obtained for the following three kinds of line-and-space patterns. The dimensions (sizes) are dimensions (sizes) in the transferred image on the wafer, and CD stands for critical dimension, which means the transferred line width.

CD 22 nm/pattern pitch 44 nm,

CD 22 nm/pattern pitch 88 nm, and

CD 44 nm/pattern pitch 88 nm.

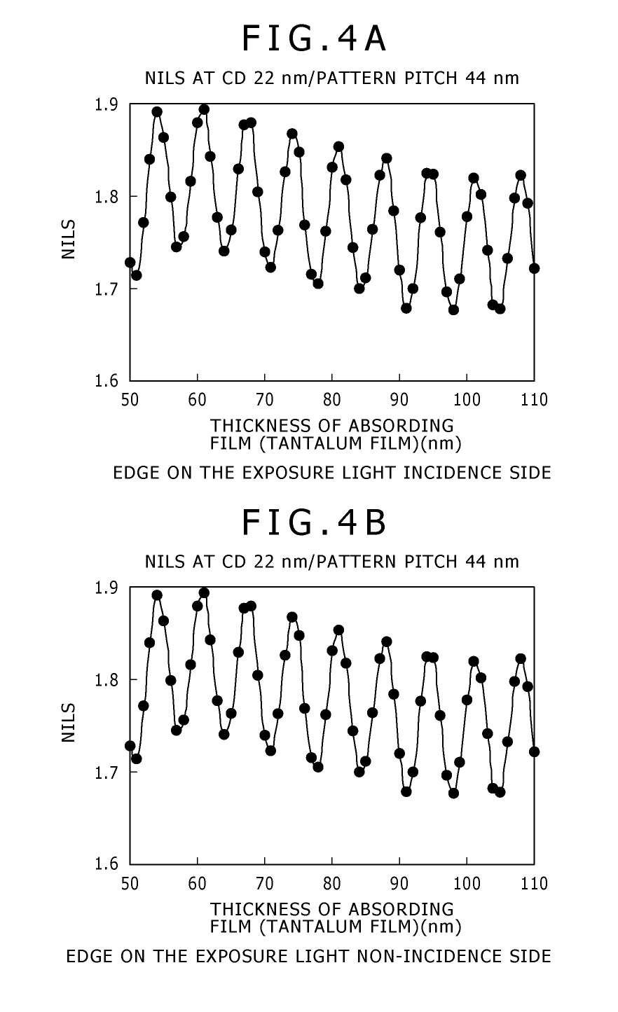

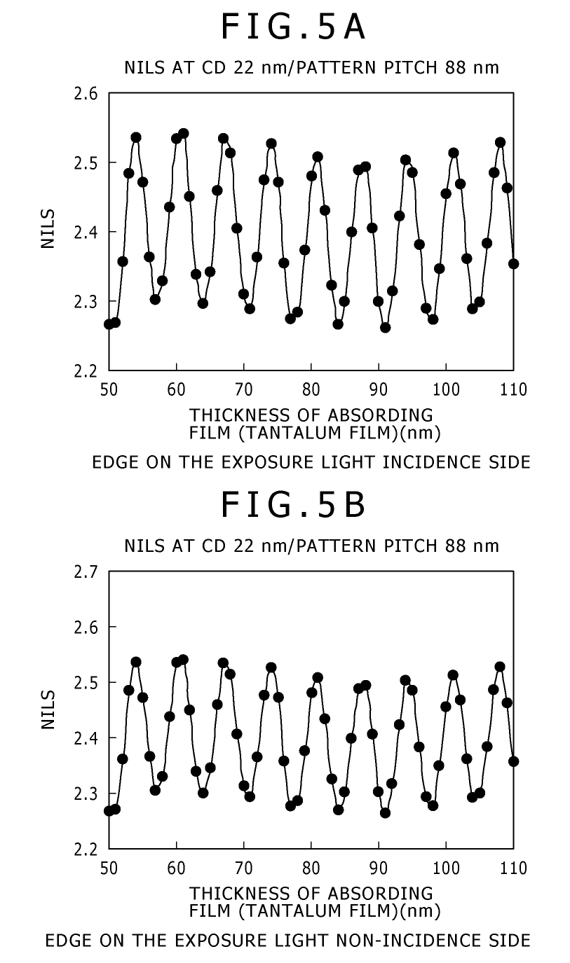

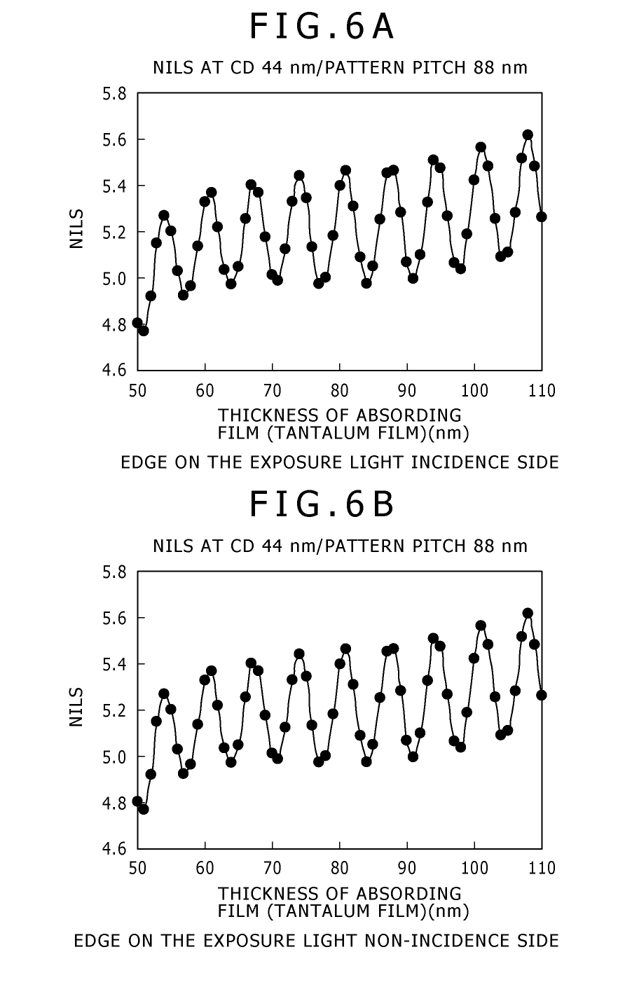

Now, FIGS. 4A and 4B show the relationship between the thickness of the absorbing film (tantalum film) and the NILS, at CD 22 nm/pattern pitch 44 nm; FIGS. 5A and 5B show the relationship between the thickness of the absorbing film (tantalum film) and the NILS, at CD 22 nm/pattern pitch 88 nm; and FIGS. 6A and 6B show the relationship between the thickness of the absorbing film (tantalum film) and the NILS, at CD 44 nm/pattern pitch 88 nm. Here, the “edge on the exposure light incidence side” corresponds to the left-side edge of the pattern of the absorbing film 13 shown in FIG. 1, while the “edge on the exposure light non-incidence side” corresponds to the right-side edge of the pattern of the absorbing film 13 shown in FIG. 1.

It is seen from these figures that the thickness values of the absorbing film 13 such as to bring the NILS to a maximal value (local maximum) are substantially the same in all the plots shown in FIGS. 4A to 6B.

Table 1 shows the optimum thickness values of the absorbing film (tantalum film) under each of the above-mentioned conditions, obtained from the minimal values of the reflectance contrast shown in FIG. 2 and the maximal values of the NILS shown in FIGS. 4A to 6B.

TABLE 1
Optimum Thickness (nm) of Absorbing Film obtained from Contrast
of Transferred Image on Wafer under Each of Various Conditions

| CD 22 nm/ | | CD 22 nm/ | | CD 44 nm/ | |
|---|---|---|---|---|---|
| Pattern Pitch 44 nm | | Pattern Pitch 68 nm | | Pattern Pitch 88 nm | |
| | Non- | | Non- | | Non- |
| Incidence | incidence | Incidence | incidence | Incidence | incidence |
| Side | Side | Side | Side | Side | Side |
| 55 | 54 | 54 | 54 | 54 | 54 |
| 61 | 61 | 61 | 61 | 61 | 60 |
| 68 | 67 | 67 | 68 | 67 | 67 |
| 74 | 74 | 74 | 74 | 74 | 74 |
| 81 | 81 | 82 | 82 | 81 | 81 |
| 88 | 88 | 88 | 88 | 88 | 87 |
| 94 | 94 | 94 | 95 | 94 | 94 |
| 101 | 101 | 101 | 101 | 101 | 101 |
| 108 | 108 | 108 | 108 | 108 | 108 |

As shown in Table 1, the optimum thickness values of the absorbing film which are obtained at the maximal values of NILS are substantially the same under any of the conditions. However, these optimum thickness values do not coincide with the optimum thickness values of the absorbing film which are obtained based on the reflectance contrast. In other words, when an optimum thickness value of the absorbing film is determined based on the reflectance contrast as in the method according to the related art, the thickness value may not necessarily give an optimum contrast of optical image.

In view of this, the condition for bringing the contrast of the transferred image on the wafer to a maximal value is added. First, a thickness of the absorbing film such as to bring the contrast of the transferred image on the wafer to a maximal value is selected, and the thickness of the absorbing film in this instance is adjusted so as to fall within a desired range of the reflectance contrast. This condition is obtained from Table 2, which summarizes the reflectance contrast values at the optimum thickness values (nm) of the absorbing film obtained from the NILS.

TABLE 2
Reflectance Contrast at Optimum Thickness (nm) of
Absorbing Film obtained from NILS

| Optimum Thickness (nm) of | Reflectance |
|---|---|
| Absorbing Film obtained from NILS | Contrast |
| 54 | 0.0267 |
| 61 | 0.0187 |
| 67 | 0.0130 |
| 74 | 0.0087 |
| 81 | 0.0059 |
| 88 | 0.0041 |
| 94 | 0.0011 |
| 101 | 0.0009 |
| 108 | 0.0009 |

As shown in Table 2, for example, when a reflectance contrast range of 0.01 (1.0%) is allowed, it suffices for the thickness of the absorbing film to be not less than 74 nm. Besides, when a reflectance contrast range of 0.005 (0.5%) is allowed, it suffices for the thickness of the absorbing film to be not less than 88 nm. According to the embodiment of the present invention, it is thus possible to simultaneously realize both a good contrast of the transferred image on the wafer and a good reflectance contrast. In determining the thickness of the absorbing film, it is preferably determined so as to minimize the reflectance contrast between the absorbing film and the mask blank.

It has been assumed that the reflectance contrast range of 0.01 (1.0%) is allowed, since a reflectance contrast lower than 1.0% leads to a lowering in the contrast of the transferred image on the wafer, making it very difficult to obtain a good resist image on the wafer. However, the resist image is not abruptly worsened with 1.0% as a criterion but is worsened gradually. Taking a photomask as an example, photomasks have been fabricated according to a contrast specification of 0.1%, but, recently, photomasks have come to be fabricated according to a contrast specification lowered to about 1%. In view of this, based on the recent trend pertaining to photomasks, the upper limit for the contrast is set with 1.0% as a yardstick.

Now, the method for simultaneously realizing both a good contrast of the transferred image on the wafer and a good reflectance contrast will be described below.

A condition is obtained under which the thickness of the absorbing film such as to bring the contrast of the transferred image on the wafer to a maximal value and the thickness of the absorbing film such as to bring the contrast of the optical image to a minimal value conform to each other. This condition can be easily obtained by comparison between the thickness values of the absorbing film such as to bring the contrast of the transferred image on the wafer to a maximal value, which are shown in Table 1 above, and the thickness values (57, 64, 71, 79, 86, 93, 100, and 107 nm) of the absorbing film such as to bring the contrast of the optical image to a minimal value, which are obtained from FIG. 2 above. With a thickness of the absorbing film of 108 nm, the contrast of the transferred image on the wafer has a maximal value, and, at the same time, the contrast of the optical image has a substantially minimal value. In this manner, both a good contrast of the transferred image on the wafer and a good reflectance contrast can be realized simultaneously.

The extreme ultraviolet rays to be applied to the exposure mask based on the present invention are usually referred to as EUV (extreme ultraviolet) rays in the field of lithography for manufacture of semiconductor devices, and are ultraviolet rays including at least the wavelengths in the range of 5 to 100 nm. Usually, the ultraviolet rays (inclusive of vacuum ultraviolet rays) are defined as rays with wavelengths of from abut 1 nm to about 380 nm. Therefore, the extreme ultraviolet rays as above-mentioned may include the ultraviolet rays with wavelengths of not more than 5 nm.

It should be understood by those skilled in the art that various modifications, combinations, sub-combinations and alterations may occur depending on design requirements and other factors insofar as they are within the scope of the appended claims or the equivalents thereof.

What is claimed is:

1. An exposure mask for use in manufacturing a semiconductor device through exposure conducted by use of extreme ultraviolet rays, comprising:
an absorbing film configured to absorb the extreme ultraviolet rays, and a mask blank having the function of reflecting the extreme ultraviolet rays,
wherein the thickness of said absorbing film is so determined that the contrast of an optical image transferred onto a wafer by use of said exposure mask will have a maximal value.

2. The exposure mask as set forth in claim 1,
wherein the thickness of said absorbing film is so determined that the contrast of said optical image transferred onto said wafer by use of said exposure mask will have a maximal value and that the reflectance contrast between said absorbing film and said mask blank will be not more than a desired value.

3. The exposure mask as set forth in claim 2,
wherein the reflectance contrast between said absorbing film and said mask blank is not more than 10%.

4. The exposure mask as set forth in claim 1,
wherein the thickness of said absorbing film is so determined that the contrast of said optical image transferred onto said wafer by use of said exposure mask will have a maximal value and that the reflectance contrast between said absorbing film and said mask blank will be a minimized.
